(19) United States
(12) Patent Application Publication
(10) Pub. No.: US 2013/0167369 A1
(43) Pub. Date: Jul. 4, 2013

(54) APPARATUSES FOR MOUNTING SEMICONDUCTOR CHIPS

(71) Applicants: Joo-Young OH, Asan-si (KR); Juhyun LYU, Cheonan-si (KR)

(72) Inventors: Joo-Young OH, Asan-si (KR); Juhyun LYU, Cheonan-si (KR)

(73) Assignee: SAMSUNG ELECTRONICS CO., LTD., Suwon-si (KR)

(21) Appl. No.: 13/618,755

(22) Filed: Sep. 14, 2012

(30) Foreign Application Priority Data
Jan. 2, 2012 (KR) 10-2012-0000272

(51) Int. Cl. H01L 21/677; H05K 3/30

(52) U.S. Cl. 29/740; 414/222.01

(57) ABSTRACT

A delivering unit for a semiconductor chip provided with a solder bump may include a shuttle configured to move translationally along a direction; at least one chip supporting plate provided on the shuttle to support the semiconductor chip; a pick-up head configured to pick up the semiconductor chip from the at least one chip supporting plate; and at least one buffering member supporting the at least one chip supporting plate and relieving an impact between the pick-up head and the semiconductor chip. A semiconductor chip mounting apparatus may include a chip providing unit configured to provide semiconductor chips having one or more solder bumps; a mounting unit configured to mount the semiconductor chips on printed circuit boards in a surface mounting manner; and a chip delivering unit configured to deliver the semiconductor chips from the chip providing unit to the mounting unit.

### CROSS-REFERENCE TO RELATED APPLICATION(S)

This application claims priority from Korean Patent Application No. 10-2012-0000272, filed on Jan. 2, 2012, in the Korean Intellectual Property Office (KIPO), the entire contents of which are incorporated herein by reference.

### BACKGROUND

1. Field

Example embodiments may relate to semiconductor chip mounting apparatuses. Example embodiments also may relate to apparatuses for mounting semiconductor chips on surfaces of printed circuit boards.

2. Description of Related Art

With increasing demands for high speed and high density of semiconductor chips, semiconductor chips have been shrunk and the number of input/output (I/O) pins thereof has been increased. As a result, a flip chip bonding technique has been widely used to mount a semiconductor chip.

In the flip chip bonding technique, a conductive bump is used to mount a semiconductor chip directly on a mounting element. Accordingly, the flip chip bonding technique has various technical advantages in terms of speed, density, and miniaturization, compared with the conventional wire bonding technique and a tape automated bonding (TAB) technique using a tape printed circuit board.

### SUMMARY

Example embodiments may provide semiconductor chip mounting apparatuses capable of reducing damage to bumps provided on semiconductor chips.

In some example embodiments, a delivering unit for a semiconductor chip provided with a solder bump may comprise a shuttle configured to move translationally along a direction; at least one chip supporting plate provided on the shuttle to support the semiconductor chip, the solder bump being disposed to face the at least one chip supporting plate; a pick-up head configured to pick up the semiconductor chip from the at least one chip supporting plate; and/or at least one buffering member supporting the at least one chip supporting plate and relieving an impact between the pick-up head and the semiconductor chip.

In some example embodiments, the pick-up head may be configured to suck a surface of the semiconductor chip opposite to the solder bump. The buffering member may comprise a spring provided between the at least one chip supporting plate and the shuttle to support the at least one chip supporting plate.

In some example embodiments, the spring may comprise a first spring supporting a first region of the at least one chip supporting plate; and/or a second spring supporting a second region of the at least one chip supporting plate spaced apart from the first region.

In some example embodiments, the pick-up head may be configured to suck a surface of the semiconductor chip opposite to the solder bump. The buffering member may comprise a pad provided between the at least one chip supporting plate and the shuttle to support the at least one chip supporting plate, the pad being formed of a buffering material.

In some example embodiments, the pad may have an area corresponding to that of the at least one chip supporting plate.

In some example embodiments, the at least one chip supporting plate may comprise a plurality of chip supporting plates. The at least one buffering member may comprise a plurality of buffering members, each of which is provided below the corresponding one of the chip supporting plates.

In some example embodiments, a semiconductor chip mounting apparatus may comprise a loading part configured to provide a semiconductor chip with a solder bump; a chip delivering unit configured to deliver the semiconductor chip from the loading part; and/or a mounting unit configured to pick up the semiconductor chip from the chip delivering unit and mounting the semiconductor chip on a printed circuit board in a surface mounting manner. The chip delivering unit may comprise a shuttle configured to move translationally along a direction; at least one chip supporting plate configured to move along with the shuttle, the semiconductor chip being disposed on the at least one chip supporting plate in such a way that the solder bump faces the at least one chip supporting plate; and/or at least one buffering member provided between the at least one chip supporting plate and the shuttle, and configured to relieve an impact between the mounting unit and the semiconductor chip.

In some example embodiments, the buffering member may comprise at least one spring provided between the at least one chip supporting plate and the shuttle to support the at least one chip supporting plate.

In some example embodiments, the at least one spring may comprise a plurality of springs arranged in parallel between the at least one chip supporting plate and the shuttle.

In some example embodiments, the buffering member may comprise a pad provided between the at least one chip supporting plate and the shuttle to support the at least one chip supporting plate, the pad being formed of a buffering material.

In some example embodiments, the at least one chip supporting plate may comprise a plurality of chip supporting plates arranged on the shuttle in a row. The at least one buffering member may comprise a plurality of buffering members, each of which is provided below the corresponding one of the chip supporting plates.

In some example embodiments, a semiconductor chip mounting apparatus may comprise a chip providing unit configured to provide semiconductor chips having one or more solder bumps; a mounting unit configured to mount the semiconductor chips on printed circuit boards in a surface mounting manner; and/or a chip delivering unit configured to deliver the semiconductor chips from the chip providing unit to the mounting unit. The chip delivering unit may comprise one or more shuttles configured to move in a first direction; one or more chip supporting plates configured to move with the one or more shuttles; and/or one or more buffering members provided between the one or more chip supporting plates and the one or more shuttles to reduce impact between the one or more solder bumps and the one or more chip supporting plates.

In some example embodiments, the one or more buffering members may comprise one or more springs between the one or more chip supporting plates and the one or more shuttles.

In some example embodiments, the one or more buffering members may comprise a plurality of springs in parallel between the one or more chip supporting plates and the one or more shuttles.

In some example embodiments, the plurality of springs may comprise first springs supporting first regions of the one or more chip supporting plates; and/or second springs supporting second regions of the one or more chip supporting plates. The first regions may be spaced apart from the second regions.

In some example embodiments, the one or more buffering members may comprise one or more pads between the one or more chip supporting plates and the one or more shuttles.

In some example embodiments, the one or more pads may comprise buffering material.

In some example embodiments, a horizontal cross-section of at least one of the one or more pads may correspond to a horizontal cross-section of at least one of the one or more chip supporting plates.

In some example embodiments, horizontal cross-sections of the one or more pads may correspond to horizontal cross-sections of the one or more chip supporting plates.

In some example embodiments, the one or more chip supporting plates may comprise a plurality of chip supporting plates on the one or more shuttles. The one or more buffering members may comprise a plurality of buffering member. The plurality of buffering members may be between the plurality of chip supporting plates and the at least one shuttle.

### BRIEF DESCRIPTION OF THE DRAWINGS

The above and/or other aspects and advantages will become more apparent and more readily appreciated from the following detailed description of example embodiments, taken in conjunction with the accompanying drawings, in which:

FIG. 1 is a schematic diagram of a semiconductor chip mounting apparatus according to some example embodiments.

FIG. 2 is a perspective view illustrating the substrate providing unit of FIG. 1.

FIG. 3 is a schematic diagram illustrating a printed circuit board.

FIG. 4 is a perspective view illustrating the semiconductor chip providing unit of FIG. 1.

FIG. 5 is a diagram illustrating semiconductor chips separated from a wafer.

FIG. 6 is a diagram exemplarily illustrating the delivering head of FIG. 1 and a process of delivering a semiconductor chip using the delivering head.

FIG. 7 is a plan view illustrating the mounting part of FIG. 1.

FIG. 8 is a sectional view illustrating the chip delivering unit of FIG. 7.

FIG. 9 is a diagram illustrating the pick-up heads of FIG. 7 and a process of picking up a semiconductor chip from the chip supporting plate using the pick-up heads.

FIG. 10 is a diagram illustrating the flux bath of FIG. 7 and a process of immersing a semiconductor chip into a flux.

FIG. 11 is a diagram illustrating a process of mounting a semiconductor chip on a printed circuit board using a pick-up head.

FIG. 12 is a diagram illustrating a process of picking up a semiconductor chip from the chip supporting plate using the pick-up heads.

FIG. 13 is a sectional view illustrating a chip delivering unit according to some example embodiments.

### DETAILED DESCRIPTION

Example embodiments will now be described more fully with reference to the accompanying drawings. Embodiments, however, may be embodied in many different forms and should not be construed as being limited to the embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when an element is referred to as being “on,” “connected to,” “electrically connected to,” or “coupled to” to another component, it may be directly on, connected to, electrically connected to, or coupled to the other component or intervening components may be present. In contrast, when a component is referred to as being “directly on,” “directly connected to,” “directly electrically connected to,” or “directly coupled to” another component, there are no intervening components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting of example embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

Example embodiments may be described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will typically have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature, their shapes are not intended to illustrate the actual shape of a region of a device, and their shapes are not intended to limit the scope of the example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Reference will now be made to example embodiments, which are illustrated in the accompanying drawings, wherein like reference numerals may refer to like components throughout.

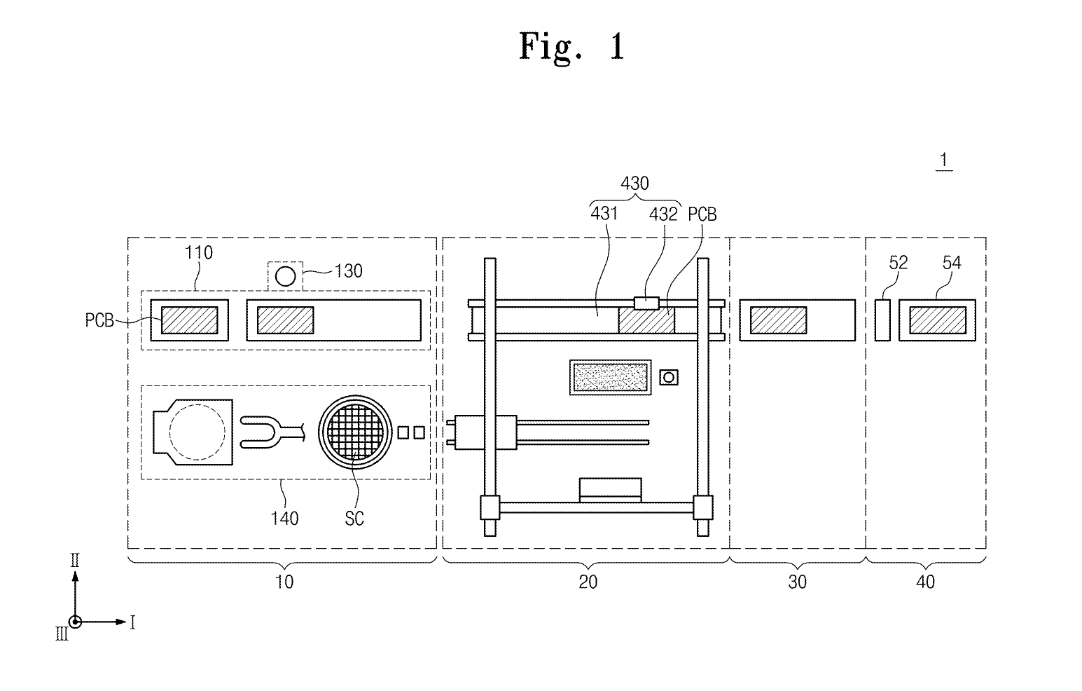

FIG. 1 is a schematic diagram of a semiconductor chip mounting apparatus according to some example embodiments.

Referring to FIG. 1, a semiconductor chip mounting apparatus 1 may include a loading part 10, a mounting part 20, a reflowing part 30, and an unloading part 40. The loading part 10, the mounting part 20, the reflowing part 30, and the unloading part 40 may be sequentially arranged in a row along a first direction I. Hereinafter, from a top plan view, a second direction II will be defined as a direction perpendicular to the first direction I, and a third direction III will be defined as a direction perpendicular to both the first direction I and the second direction II according to the Right Hand Rule.

The loading part 10 may be disposed adjacent to a front side of the mounting part 20 to provide a semiconductor chip SC and an interconnection substrate PCB to the mounting part 20. The semiconductor chip SC may include a flip chip with solder bumps. The interconnection substrate PCB may be a printed circuit board provided with connecting pads and circuit interconnections. The mounting part 20 may be configured to mount the semiconductor chip SC onto a surface of the interconnection substrate PCB. The reflowing part 30 may be disposed adjacent to a back side of the mounting part 20 and be configured to reflow the solder bumps of the semiconductor chip SC. As the result of the reflowing, the solder bumps of the semiconductor chip SC may be bonded to contacting pads of the interconnection substrate PCB. The unloading part 40 may be disposed adjacent to a back side of the reflowing part 30 and be configured to unload the interconnection substrate PCB bonded with the semiconductor chip SC. Hereinafter, each of the parts will be described in more detail.

The loading part 10 may include a substrate providing unit 110, a detector 130, and a semiconductor chip providing unit 140. The substrate providing unit 110 may be configured to provide the interconnection substrate PCB into the mounting part 20. The detector 130 may be disposed at one side of the substrate providing unit 110 to decipher a reject mark on the interconnection substrate PCB. The reject mark may be configured to contain information on whether there is a failure or not in a chip mounting region of the interconnection substrate PCB. The semiconductor chip providing unit 140 may be disposed at one side of the substrate providing unit 110 in the second direction II. The semiconductor chip providing unit 140 may be configured to provide the semiconductor chip SC into the mounting part 20.

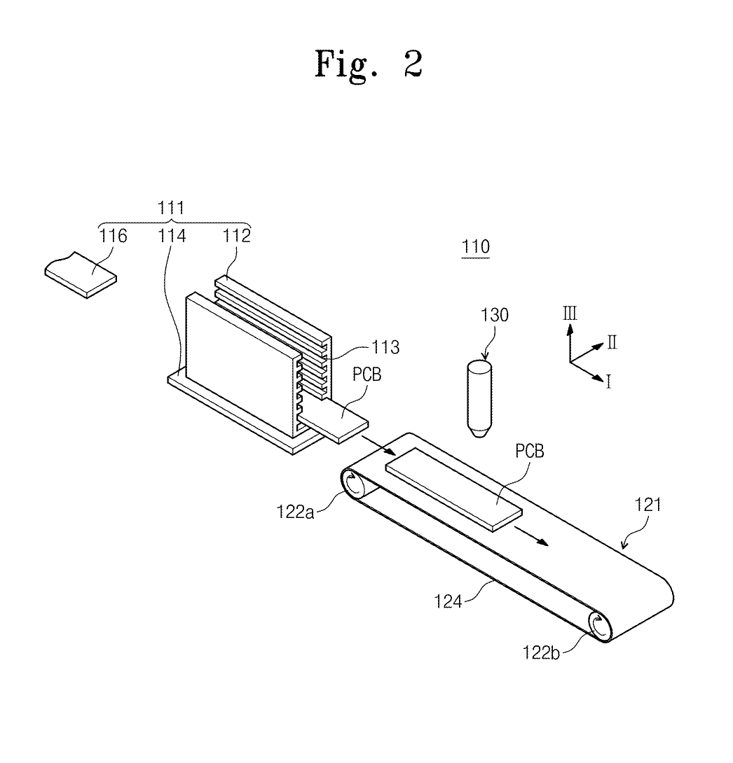

FIG. 2 is a perspective view illustrating the substrate providing unit of FIG. 1. Referring to FIG. 2, the substrate providing unit 110 may include a loader 111 and a conveyer 121. The loader 111 may be configured to load the interconnection substrate PCB and transfer the interconnection substrate PCB to the conveyer 121. The conveyer 121 may be configured to deliver the interconnection substrate PCB to the mounting part 20.

The loader 111 may load the interconnection substrate PCB in a magazine manner or in such a way that the interconnection substrate PCB is inserted into a slot 113 provided in a magazine 112. The loader 111 may include the magazine 112, a lift table 114, and a pusher 116. The magazine 112 may be provided along the first direction I and have an open-box structure, whose front, back, and top sides are open. In the magazine 112, slots 113 may be provided along the third direction III to contain the interconnection substrates PCB.

The magazine 112 may be loaded on the lift table 114, which can be vertically moved by a driving element (not shown). The pusher 116 may be disposed at a front side of the magazine 112 and be configured to push out one of the interconnection substrates PCB contained in the magazine 112 toward the first direction I. For example, in the case in which one of the interconnection substrates PCB is pushed out from the magazine 112 by the pusher 116, a vertical position of the magazine 112 may be elevated using the driving element, and thereafter, another interconnection substrate PCB may be pushed out from the magazine 112 by the pusher 116.

The conveyer 121 may be disposed adjacent to a back side of the magazine 112 along the first direction I. The conveyer 121 may include rollers 122a and 122b, which are separated from and parallel to each other in the first direction I, and a conveyer belt 124 wound on the rollers 122a and 122b. The interconnection substrate PCB drawn from the magazine 112 may be laid on the conveyer belt 124. An upper portion of the conveyer belt 124 may be moved along the first direction I by clockwise rotations of the rollers 122a and 122b and, thus, the interconnection substrate PCB laid on the conveyer belt 124 can be moved in the first direction I. In example embodiments, a printed circuit board supporting part 430 may be provided at a back-end portion of the conveyer 121, and the interconnection substrate PCB may be delivered to the printed circuit board supporting part 430 by the conveyer 121.

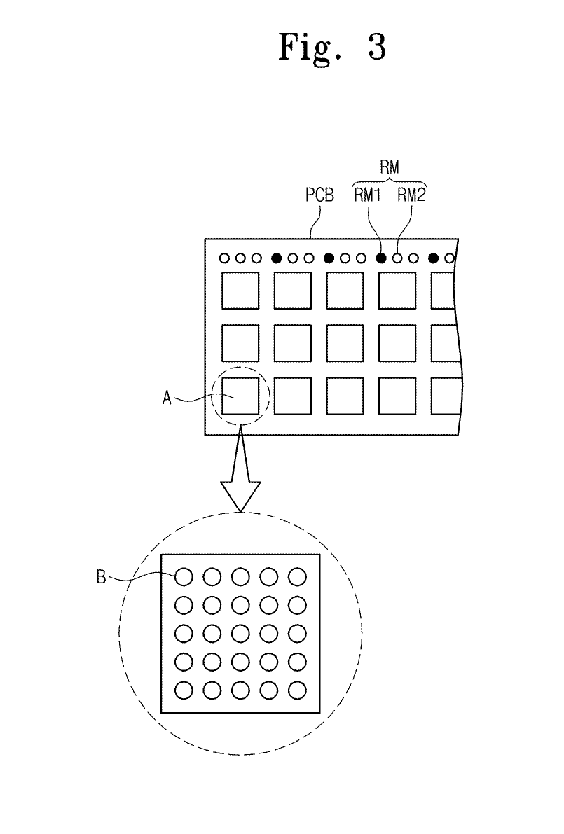

The detector 130 may be disposed near the conveyer 121 and decipher the reject mark on the interconnection substrate PCB to be delivered by the conveyer 121. As shown in FIG. 3, on an upper surface of the interconnection substrate PCB, the reject marks RM may be arranged in a row around a plurality of chip mounting regions A. A plurality of connecting pads B bonded with solder bumps of a semiconductor chip may be provided on the chip mounting regions A, respectively. The number of the reject marks RM may be substantially equal to that of the chip mounting regions A, and the reject marks RM may be formed to indicate whether there is a failure in the chip mounting region A. For example, a first reject mark RM1 of black may be used to indicate that there is a failure in the corresponding chip mounting region A, while a second reject mark RM2 of white may be used to indicate that there is no failure.

The deciphering of the reject marks RM of the interconnection substrate PCB enables the semiconductor chip mounting apparatus 1 to determine whether the chip mounting region A has a failure. Based on the deciphering results transferred from the detector 130, the mounting part 20 may mount semiconductor chips on only the chip mounting regions A that do not have a failure.

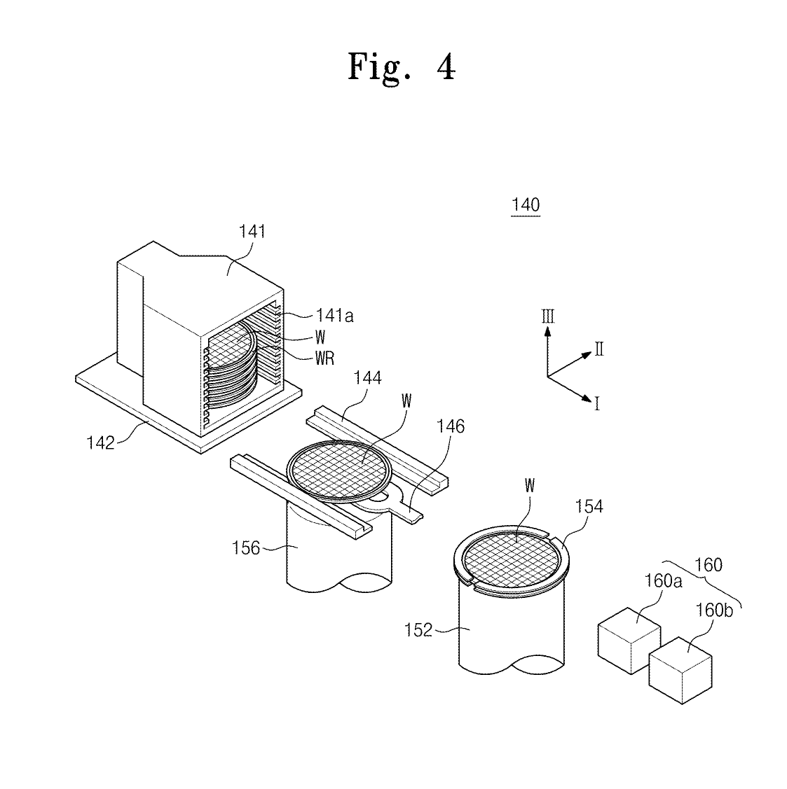

FIG. 4 is a perspective view illustrating the semiconductor chip providing unit of FIG. 1. Referring to FIG. 4, the semiconductor chip providing unit 140 may be configured to provide a semiconductor chip to the mounting part 20. The semiconductor chip providing unit 140 may include a wafer cassette 141, a wafer delivering device 146, a wafer supporting part 152, a tape expander 154, and a delivering head 160.

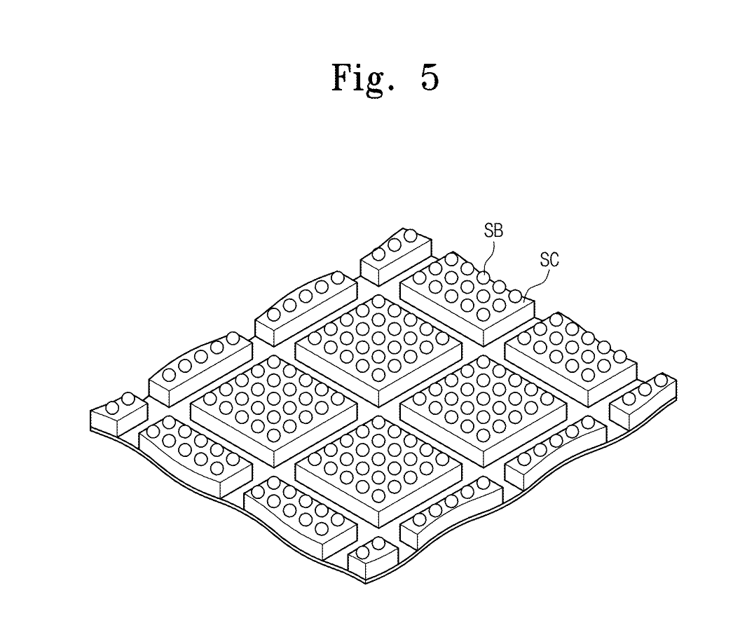

The wafer cassette 141 may be laid on a cassette supporting element 142. The wafer cassette 141 may be configured to have slots 141a, in which the wafers W are contained. The wafers W to be contained in the slots 141a may be wafers to which fabrication (FAB), back-grinding, and sawing processes may have been applied. In other words, an ultraviolet light tape for a dicing process may be attached to a rear surface of the wafer W, and an edge of the wafer W may be supported by a wafer ring WR. As shown in FIG. 5, the semiconductor chips SC formed in the wafer W may be independently separated from each other using a sawing process. A plurality of solder bumps SB may be provided on a top surface of the semiconductor chip SC. Hereinafter, a bump surface may be used to refer to a surface of the semiconductor chip SC provided with the solder bump SB, and a suction surface may be used to refer to another surface of the semiconductor chip SC on which the solder bump SB is not provided and which faces the bump surface.

The wafer delivering device 146 may be configured to unload the wafer W from the wafer cassette 141 and take it down on a loading rail 144. An ultraviolet light irradiating device 156 may be provided below the loading rail 144. The ultraviolet light irradiating device 156 may be configured to irradiate an ultraviolet light onto the ultraviolet light tape attached to the bottom surface of the wafer W and weaken adhesion strength of the tape.

The wafer supporting part 152 may be disposed at one side of the loading rail 144. The wafer W disposed on the loading rail 144 may be delivered to the wafer supporting part 152 by the wafer delivering device 146 and be supported by the wafer supporting part 152. The tape expander 154 may be provided on the wafer supporting part 152. The tape expander 154 may be configured to pull a wafer ring and an ultraviolet light tape for a dicing process, such that the semiconductor chip SC on the wafer can be easily picked up.

The delivering head 160 may be disposed between the wafer supporting part 152 and the mounting part 20. The delivering head 160 may be configured to pick up each of the semiconductor chips SC provided on the wafer W and deliver it to the mounting part 20.

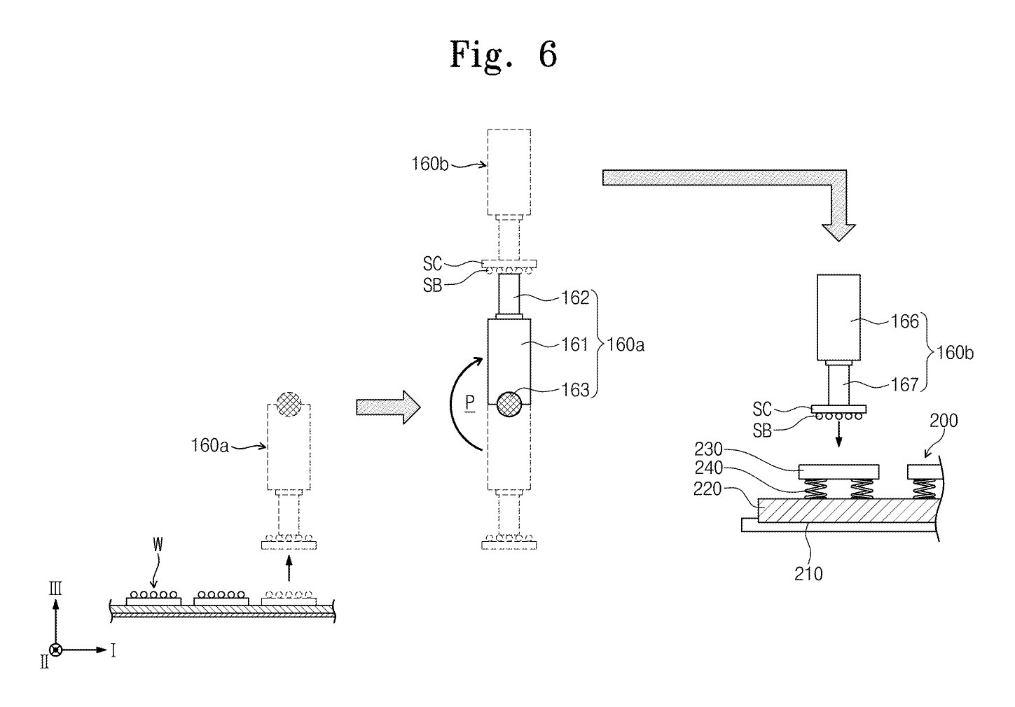

FIG. 6 is a diagram exemplarily illustrating the delivering head of FIG. 1 and a process of delivering a semiconductor chip using the delivering head.

Referring to FIG. 6, the delivering head 160 may include a flip head 160a and a landing head 160b.

The flip head 160a may be configured to pick up and flip the semiconductor chips SC provided on the wafer W. The flip head 160a may be configured to be able move in a section between a position over the wafer W and a position P where the semiconductor chip SC may be flipped. The flip head 160a may include a body 161, a flip rod 162, and an axis rod 163. The flip rod 162 may be provided at one endpoint of the body 161 and be movable with respect to the body 161. As a result, a position of an endpoint of the flip rod 162 is movable. A suction hole (not shown) may be formed in a bottom surface of the flip rod 162. In the case of picking up the semiconductor chip SC, the suction hole may be decompressed to be able to suck the bump surface of the semiconductor chip SC. The suction hole may be maintained in the decompressed state during the operation of the flip head 160a. The axis rod 163 may be provided on the body 161. The body 161 may be configured to be rotatable with respect to the axis rod 163. For example, the body 161 may be rotatable around the axis rod 163 by about 180 degrees, and thus, the bump surface of the semiconductor chip SC can be flipped to face downward.

The landing head 160b may be disposed between the flip head 160a and the mounting part 20. The semiconductor chip SC flipped by the flip head 160a may be delivered to the mounting part 20 by the landing head 160b. The landing head 160b may include a body 166 and a landing rod 167. The landing rod 167 may be moved relative to the body 166 in such a way that a bottom surface thereof can be varied. A suction hole (not shown) may be provided in the bottom surface of the landing rod 167. The suction hole may be decompressed to be able to suck a suction surface of the semiconductor chip SC.

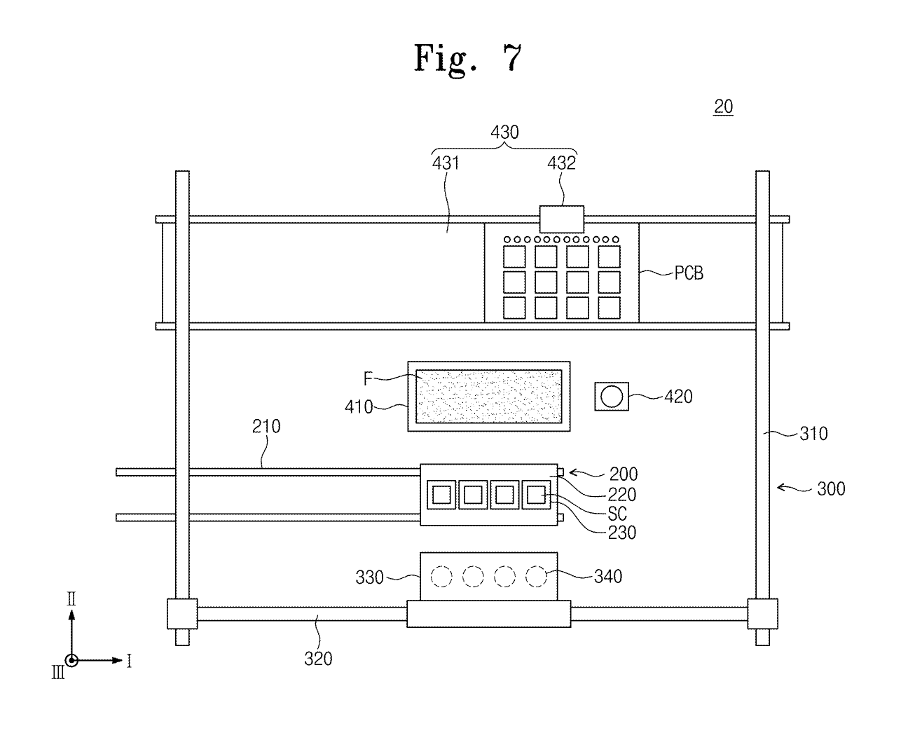

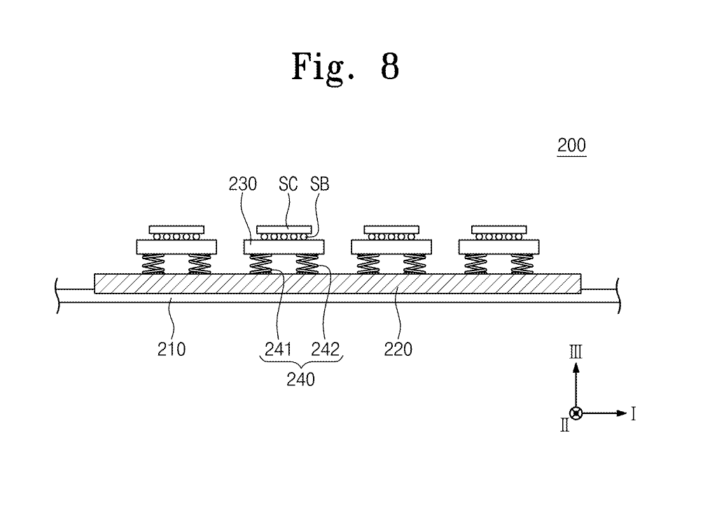

FIG. 7 is a plan view illustrating the mounting part of FIG. 1, and FIG. 8 is a sectional view illustrating the chip delivering unit of FIG. 7.

Referring to FIG. 7 and FIG. 8, the mounting part 20 may include a chip delivering unit 200, a mounting unit 300, a flux bath 410, an optical inspection unit 420, and a printed circuit board supporting part 430.

The chip delivering unit 200 may be configured to deliver the semiconductor chip SC delivered from the landing head 160b in a specific direction. For example, the chip delivering unit 200 may be configured to deliver the semiconductor chip SC along the first direction I. The chip delivering unit 200 may include guide rails 210, shuttles 220, at least one chip supporting plate 230, and a buffering member 240. The guide rails 210 may be disposed to be parallel to each other along the first direction I. The shuttle 220 may be shaped like a thin rectangular plate and be equipped on the guide rail 210. The shuttle 220 may be translationally movable along the guide rail 210 (i.e., along the first direction I).

The chip supporting plate 230 may be provided on the shuttle 220. The chip supporting plate 230 may be spaced apart from a top surface of the shuttle 220 by a specific interval. The chip supporting plate 230 may be shaped like a thin tetragonal plate. The semiconductor chip SC may be provided on a top surface of the chip supporting plate 230. The semiconductor chip SC may be disposed in such a way that a bump surface thereof may face downward, and the solder bump SB may be in contact with a top surface of the chip supporting plate 230. The chip supporting plate 230 may have an area larger than the semiconductor chip SC. The at least one chip supporting plate 230 may include a plurality of the chip supporting plates 230, which may be spaced apart from each other in a row. The chip supporting plate 230 may be formed of a flexible material. For example, the chip supporting plate 230 may be formed of a silicone-containing material. This forming enables the semiconductor chip mounting apparatus 1 to reduce damage that may result from a collision between the chip supporting plate 230 and the solder bump SB.

The buffering member 240 may be provided between the shuttle 220 and the chip supporting plate 230. The buffering member 240 may be configured to fasten the chip supporting plate 230 to the shuttle 220 and support the chip supporting plate 230. The buffering member 240 may be configured to reduce an impact between the chip supporting plate 230 and the solder bump SB, which may be caused by a force applied to the semiconductor chip SC. In example embodiments, the buffering member 240 may include one or more springs. Upper and lower end portions of the buffering member 240 may be fixed to the chip supporting plate 230 and the shuttle 220, respectively. Each of the chip supporting plates 230 may include a plurality of buffering members 240. The buffering members 240 may be arranged in parallel to support the corresponding one of the chip supporting plates 230. Each of the buffering members 240 may be configured to support different portions of the chip supporting plate 230 from each other. For example, a first spring 241 may support a first region of the chip supporting plate 230, and a second spring 242 may support a second region of the chip supporting plate 230. Here, the first and second regions of the chip supporting plate 230 may be different regions from each other. The parallel arrangement of the first and second springs 241 and 242 may prevent the chip supporting plate 230 from being leaned, when an external force is applied at an offset portion of the chip supporting plate 230. This enables the semiconductor chip mounting apparatus 1 to maintain horizontality of the semiconductor chip SC. In example embodiments, the number of the buffering members 240 may be variously modified.

The mounting unit 300 may be configured to pick up and deliver the semiconductor chip SC provided on the chip supporting plate 230. For example, the mounting unit 300 may deliver the semiconductor chip SC along the second direction II. The mounting unit 300 may include first guide rods 310, a second guide rod 320, a moving block 330, and a pick-up head 340.

The first guide rods 310 may be provided in a pair and be parallel to each other in the second direction II. For example, in the second direction II, an end portion of each first guide rod 310 may be positioned adjacent to a front side of the guide rail 210 and other portion thereof may be positioned adjacent to a rear side of the printed circuit board supporting part 430. The second guide rod 320 may be provided between the first guide rods 310 to have a longitudinal axis parallel to the first direction I. Both end portions of the second guide rod 320 may be coupled to the first guide rods 310, respectively, in such a way that the second guide rod 320 may be movable along the first guide rods 310. A driving element (not shown) may be further provided to move the second guide rod 320 in a translational manner along the first guide rods 310 or along the second direction II. The moving block 330 may be provided on the second guide rod 320. The moving block 330 may be movable along the second guide rod 320 or along the first direction I by a driving element (not shown). The pick-up heads 340 may be equipped on the moving block 330.

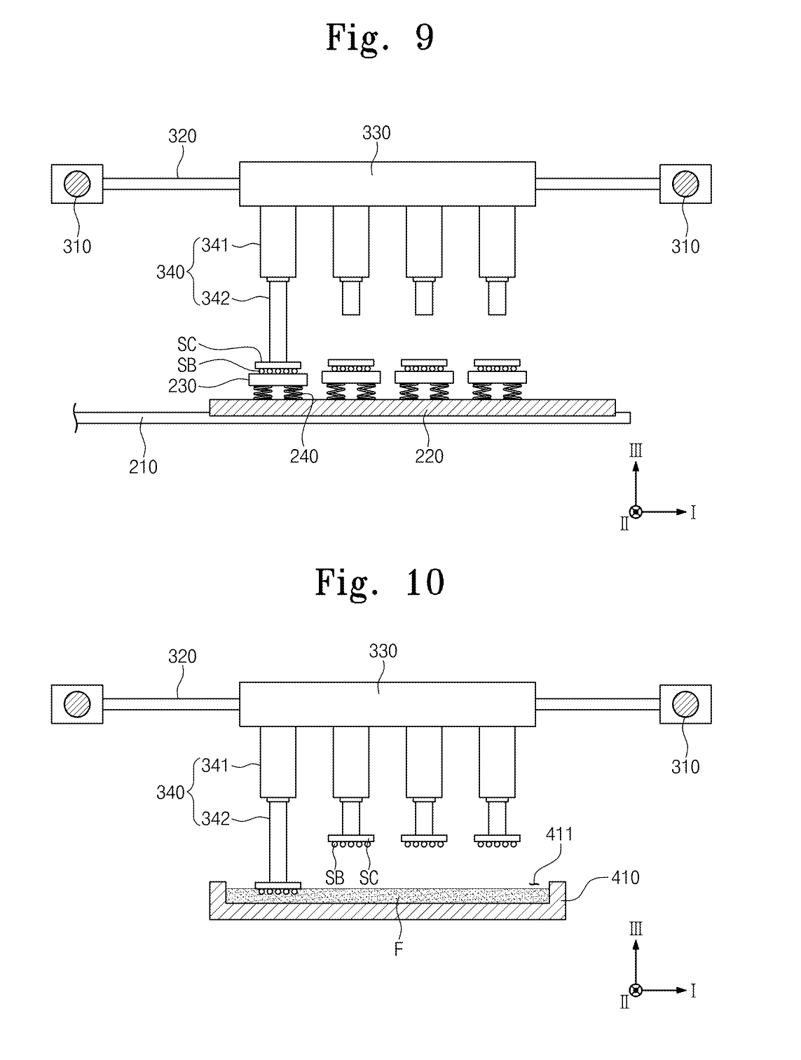

FIG. 9 is a diagram illustrating the pick-up heads of FIG. 7 and a process of picking up a semiconductor chip from the chip supporting plate using the pick-up heads. Referring to FIG. 7 and FIG. 9, a plurality of the pick-up heads 340 may be provided in a row along the first direction I. The pick-up heads 340 may be provided in such a way that the number thereof is substantially equivalent to that of the chip supporting plates 230 and the space therebetween is substantially equivalent to that between the chip supporting plates 230. The pick-up heads 340 may include a body 341 and pick-up rods 342. The body 341 may be fixed and equipped to a bottom surface of the moving block 330. The body 341 may be disposed to have a longitudinal axis parallel to the third direction III. The pick-up rod 342 may be provided below the body 341. The pick-up rods 342 may be movable in the third direction III with respect to the body 341. As a result, the pick-up rods 342 may have bottom surfaces whose vertical levels may be changeable. A suction hole (not shown) may be formed in the bottom surface of each pick-up rod 342. The suction hole may be decompressed to be able to suck the suction surface of the semiconductor chip SC. The suction hole may be maintained in the decompressed state during the suction operation of the pick-up head 340. In example embodiments, the pick-up heads 340 may be configured to control all or each of them. Furthermore, all or each of the pick-up rods 342 may be movable in the third direction III, and all or each of the suction holes may be decompressed.

The flux bath 410 may be positioned between the guide rail 210 and the printed circuit board supporting part 430 in the second direction II.

FIG. 10 is a diagram illustrating the flux bath of FIG. 7 and a process of immersing a semiconductor chip into a flux. Referring to FIG. 7 and FIG. 10, a containing part 411 with an open top surface may be provided in the flux bath 410. The containing part 411 may be filled with a flux F. The semiconductor chips SC, which may be sucked by the pick-up heads 340, may be immersed into the flux F before they are bonded to contacting pads of the interconnection substrate PCB. The semiconductor chip SC may be immersed in such a way that the solder bump SB may be sufficiently coated with the flux F. The flux F may include a material capable of removing an oxide layer from the solder bump SB. In addition, when the semiconductor chip SC is mounted on a surface of the interconnection substrate PCB, the flux F may bond the solder bump SB provisionally to the connecting pad of the interconnection substrate PCB.

The optical inspection unit 420 may be provided at one side of the flux bath 410 in the first direction I. The optical inspection unit 420 may be configured to analyze standard position information of the chip mounting region on the interconnection substrate PCB and information on a position of the solder bump SB of the semiconductor chip SC, which may be sucked by the pick-up head 340. Based on the positional information, the solder bumps SB of the semiconductor chip SC may be aligned to the connecting pad of the interconnection substrate PCB. In example embodiments, the optical inspection unit 420 may be a camera.

A control part (not shown) may be provided to control movements of the pick-up head 340, the moving block 330, and the second guide rod 320. The control part may be configured to perform a series of operations of picking up the semiconductor chip SC with the pick-up head 340, immersing the picked-up semiconductor chip SC into the flux F, optically inspecting the solder bump SB, mounting the semiconductor chip SC to the connecting pad of the interconnection substrate PCB, in a successive or continuous manner.

In the following it will be described how the semiconductor chip mounting apparatus with the afore-described configuration may be used to mount the semiconductor chip to the connecting pad of the printed circuit board.

Referring back to FIG. 1 and FIG. 2, the interconnection substrate PCB may be delivered from the conveyer 121 provided in the loading part 10 to a printed circuit board delivering rail 431. The interconnection substrate PCB may be moved to a position for performing a mounting process by a delivering gripper 432.

Referring back to FIG. 4, the wafer delivering device 146 may be configured to withdraw the wafer W from the wafer cassette 141 and provide it to the wafer supporting part 152. The semiconductor chip SC may be provided on the wafer W in such a way that the top surface thereof faces upward. Referring to FIG. 6, the flip rod 162 of the flip head 160a may be lowered to pick up the semiconductor chip SC provided on the wafer. The suction hole, which may be formed in the bottom surface of the flip rod 162, may be decompressed to suck the solder bump SB of the semiconductor chip SC. The flip head 160a with the semiconductor chip SC may be moved to a position P, where a transferring operation of the semiconductor chip will be performed. At the transferring position P, the flip head 160a may be rotated with respect to the axis rod 163 by 180 degrees, such that the top surface of the semiconductor chip SC may be flipped to face downward. The landing head 160b may be moved to the transferring position P and receive the flipped semiconductor chip SC. The landing rod 167 may suck the bottom surface of the semiconductor chip SC using the decompressed suction hole provided in the bottom surface thereof. The landing head 160b may deliver the semiconductor chip SC onto the chip supporting plate 230. The shuttle 220 may be moved to deliver the semiconductor chip SC along the guide rail 210 or along the first direction I.

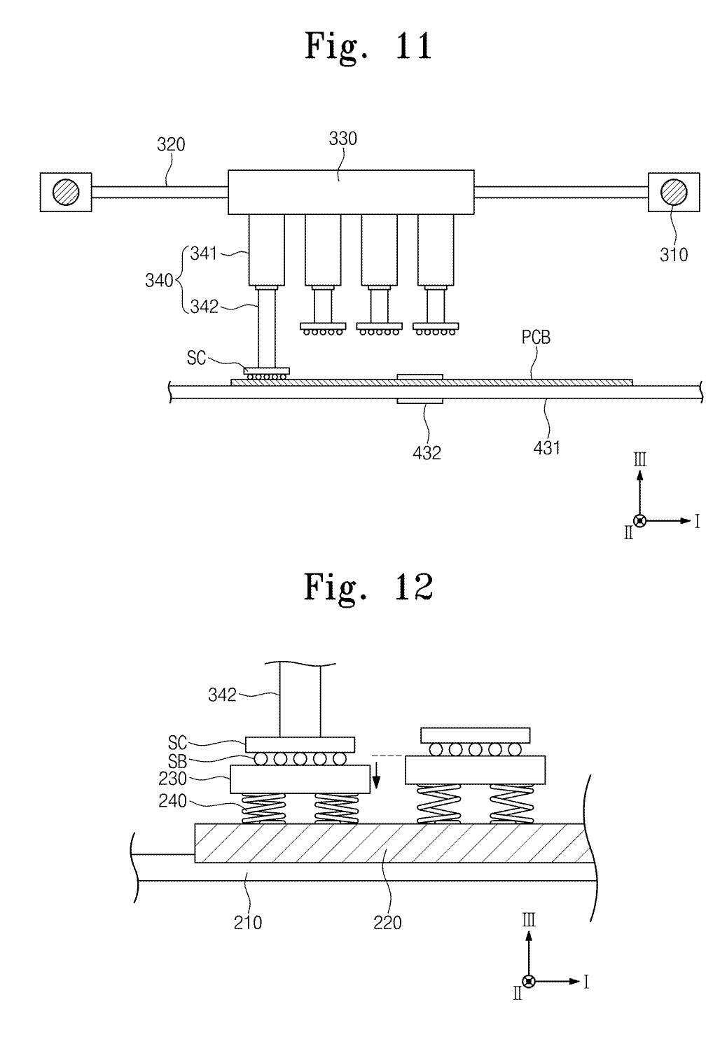

As shown in FIGS. 7 and 9, the pick-up head 340 may be located on the semiconductor chip SC and the pick-up rod 342 may be lowered. The bottom surface of the pick-up rod 342 may be in contact with the suction surface of the semiconductor chip SC. The pick-up rod 342 may pick up the semiconductor chip SC from the chip supporting plate 230 in a suction manner. The second guide rod 320 may be moved in the second direction II, such that the pick-up head 340 may be positioned over the flux bath 410 as shown in FIG. 10. The pick-up rod 342 may be moved downward and upward to immerse the solder bump SB of the semiconductor chip SC into the flux F. Thereafter, the pick-up head 340 may be located over an optical inspection unit 420 by the moving block 330 and the second guide rod 320, and the optical inspection unit 420 may analyze positional information of the solder bump SB of the semiconductor chip SC. After the optical inspection, based on the analyzed positional information of the solder bump SB, the semiconductor chip SC may be mounted on the surface of the interconnection substrate PCB, as shown in FIG. 11.

During the operations of loading the semiconductor chip SC onto the chip supporting plate 230 and picking up the semiconductor chip SC from the chip supporting plate 230, the semiconductor chip SC and the solder bump SB may be pressured by the landing rod 167 and the pick-up rod 342. In the case in which the landing rod 167 and the pick-up rod 342 exert directly a pressure on the semiconductor chip SC and the solder bump SB, the solder bump SB may be departed from the semiconductor chip SC or damaged by impact with the chip supporting plate 230, because of relatively vulnerability of the solder bump SB in terms of shearing stress property. By contrast, a pressure exerted on the semiconductor chip SC from the landing rod 167 or the pick-up rod 342 may be relieved by the buffering member 240; that is, due to the presence of the buffering member 240, it is possible to reduce an impact between the solder bump SB and the chip supporting plate 230. For example, as shown in FIG. 12, due to a downward force exerted on the semiconductor chip SC by the pick-up rod 342, the buffering member 240 may be contracted and the chip supporting plate 230 may be moved downward. As a result, the resultant impact between the solder bump SB and the chip supporting plate 230 may be effectively reduced.

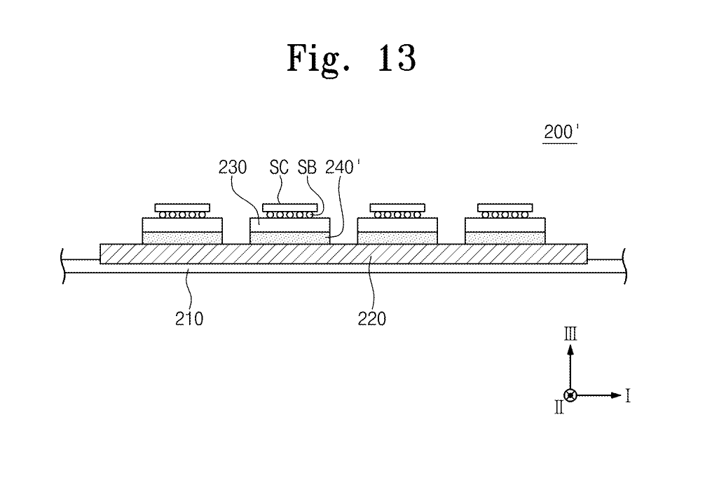

FIG. 13 is a sectional view illustrating a chip delivering unit 200′ according to some example embodiments. Referring to FIG. 13, a pad 240′ may be provided between the chip supporting plates 230 and the shuttle 220. The pad 240′ may be formed of a buffering material. The pad 240′ may have an area corresponding to that of the chip supporting plate 230. The pad 240′ may relieve an impact between the solder bump SB and the chip supporting plate 230, which may occur during the operations of loading the semiconductor chip SC onto the chip supporting plate 230 and picking up the semiconductor chip SC from the chip supporting plate 230, thereby preventing the solder bump SB from being departed or damaged.

According to some example embodiments, it is possible to absorb effectively an impact, which may be exerted to a bump of a semiconductor chip. As a result, the bump can be prevented from being damaged.

While example embodiments have been particularly shown and described, it will be understood by those of ordinary skill in the art that various changes in form and details may be made therein without departing from the spirit and scope of the present invention as defined by the following claims.

What is claimed is:

1. A delivering unit for a semiconductor chip provided with a solder bump, the delivering unit comprising:
a shuttle configured to move translationally along a direction;
at least one chip supporting plate provided on the shuttle to support the semiconductor chip, the solder bump being disposed to face the at least one chip supporting plate;
a pick-up head configured to pick up the semiconductor chip from the at least one chip supporting plate; and
at least one buffering member supporting the at least one chip supporting plate and relieving an impact between the pick-up head and the semiconductor chip.

2. The delivering unit of claim 1, wherein the pick-up head is configured to suck a surface of the semiconductor chip opposite to the solder bump, and
wherein the buffering member comprises a spring provided between the at least one chip supporting plate and the shuttle to support the at least one chip supporting plate.

3. The delivering unit of claim 2, wherein the spring comprises:
a first spring supporting a first region of the at least one chip supporting plate; and
a second spring supporting a second region of the at least one chip supporting plate spaced apart from the first region.

4. The delivering unit of claim 1, wherein the pick-up head is configured to suck a surface of the semiconductor chip opposite to the solder bump, and
wherein the buffering member comprises a pad provided between the at least one chip supporting plate and the shuttle to support the at least one chip supporting plate, the pad being formed of a buffering material.

5. The delivering unit of claim 4, wherein the pad has an area corresponding to that of the at least one chip supporting plate.

6. The delivering unit of claim 1, wherein the at least one chip supporting plate comprises a plurality of chip supporting plates, and
wherein the at least one buffering member comprises a plurality of buffering members, each of which is provided below the corresponding one of the chip supporting plates.

7. A semiconductor chip mounting apparatus, comprising:
a loading part configured to provide a semiconductor chip with a solder bump;
a chip delivering unit configured to deliver the semiconductor chip from the loading part; and
a mounting unit configured to pick up the semiconductor chip from the chip delivering unit and mounting the semiconductor chip on a printed circuit board in a surface mounting manner;
wherein the chip delivering unit comprises:
a shuttle configured to move translationally along a direction;
at least one chip supporting plate configured to move along with the shuttle, the semiconductor chip being disposed on the at least one chip supporting plate in such a way that the solder bump faces the at least one chip supporting plate; and
at least one buffering member provided between the at least one chip supporting plate and the shuttle, and configured to relieve an impact between the mounting unit and the semiconductor chip.

8. The apparatus of claim 7, wherein the buffering member comprises at least one spring provided between the at least one chip supporting plate and the shuttle to support the at least one chip supporting plate.

9. The apparatus of claim 8, wherein the at least one spring comprises a plurality of springs arranged in parallel between the at least one chip supporting plate and the shuttle.

10. The apparatus of claim 7, wherein the buffering member comprises a pad provided between the at least one chip supporting plate and the shuttle to support the at least one chip supporting plate, the pad being formed of a buffering material.

11. The apparatus of claim 7, wherein the at least one chip supporting plate comprises a plurality of chip supporting plates arranged on the shuttle in a row, and wherein the at least one buffering member comprises a plurality of buffering members, each of which is provided below the corresponding one of the chip supporting plates.

12. A semiconductor chip mounting apparatus, comprising:
a chip providing unit configured to provide semiconductor chips having one or more solder bumps;
a mounting unit configured to mount the semiconductor chips on printed circuit boards in a surface mounting manner; and
a chip delivering unit configured to deliver the semiconductor chips from the chip providing unit to the mounting unit;
wherein the chip delivering unit comprises:
one or more shuttles configured to move in a first direction;
one or more chip supporting plates configured to move with the one or more shuttles; and
one or more buffering members provided between the one or more chip supporting plates and the one or more shuttles to reduce impact between the one or more solder bumps and the one or more chip supporting plates.

13. The apparatus of claim 12, wherein the one or more buffering members comprise one or more springs between the one or more chip supporting plates and the one or more shuttles.

14. The apparatus of claim 12, the one or more buffering members comprise a plurality of springs in parallel between the one or more chip supporting plates and the one or more shuttles.

15. The delivering unit of claim 14, wherein the plurality of springs comprises:
first springs supporting first regions of the one or more chip supporting plates; and
second springs supporting second regions of the one or more chip supporting plates;
wherein the first regions are spaced apart from the second regions.

16. The apparatus of claim 12, wherein the one or more buffering members comprise one or more pads between the one or more chip supporting plates and the one or more shuttles.

17. The apparatus of claim 16, wherein the one or more pads comprise buffering material.

18. The apparatus of claim 16, wherein a horizontal cross-section of at least one of the one or more pads corresponds to a horizontal cross-section of at least one of the one or more chip supporting plates.

19. The apparatus of claim 16, wherein horizontal cross-sections of the one or more pads correspond to horizontal cross-sections of the one or more chip supporting plates.

20. The apparatus of claim 12, wherein the one or more chip supporting plates comprise a plurality of chip supporting plates on the one or more shuttles,
wherein the one or more buffering members comprise a plurality of buffering members, and
wherein the plurality of buffering members are between the plurality of chip supporting plates and the at least one shuttle.
